(19) United States
(12) Patent Application Publication
(10) Pub. No.: US 2025/0191892 A1
(43) Pub. Date: Jun. 12, 2025

(54) SUBSTRATE PROCESSING METHOD, PROCESSING MODULE, AND SEMICONDUCTOR MANUFACTURING EQUIPMENT INCLUDING THE SAME

(71) Applicant: SEMES CO., LTD., Cheonan-si (KR)

(72) Inventors: Soon Cheon CHO, Cheonan-si (KR); Ga Young KIM, Cheonan-si (KR); Jeong Woo HA, Cheonan-si (KR)

(73) Assignee: SEMES CO., LTD., Cheonan-si (KR)

(21) Appl. No.: 18/922,995

(22) Filed: Oct. 22, 2024

(30) Foreign Application Priority Data
Dec. 12, 2023 (KR) 10-2023-0179878

(51) Int. Cl. H01J 37/32

(52) U.S. Cl. CPC H01J 37/32522; H01J 37/32091; H01J 2237/3341

(57) ABSTRACT

Disclosed is a substrate processing method capable of shortening a stand-by time between processing processes. The substrate processing method using plasma includes performing a processing process on a first substrate in the state in which the first substrate is seated on a support unit in a chamber defining a processing space therein and the temperature of the first substrate is maintained at a first temperature, forming plasma in the processing space to increase the temperature of the first substrate to a second temperature, higher than the first temperature, when the processing process performed on the first substrate is completed, transferring the first substrate to the outside of the chamber when the temperature of the first substrate reaches the second temperature and placing a second substrate onto the support unit, and lowering the temperature of the second substrate to the first temperature and performing a processing process on the second substrate.

### CROSS-REFERENCE TO THE RELATED APPLICATION

The present application claims priority to and the benefit of Korean Patent Application No. 10-2023-0179878, filed on Dec. 12, 2023, in the Korean Intellectual Property Office, the entire disclosure of which is incorporated herein by reference.

### BACKGROUND

### Technical Field

The present disclosure relates to a substrate processing method of processing a substrate using plasma, a processing module, and semiconductor manufacturing equipment including the same.

### Description of the Related Art

A semiconductor manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A plasma processing process is performed in such a manner that a substrate is seated at a lower portion in a chamber defining a plasma processing space, process gas for plasma processing is supplied, and power is applied by electrodes located at an upper portion and a lower portion in the chamber.

Among plasma processing processes, a process of performing plasma processing in an ultra-low temperature environment (below 0° C.) is known. When a substrate is completely processed in an ultra-low temperature environment, the substrate is discharged to the outside of a chamber, and a next substrate is introduced into the chamber. However, when the substrate is discharged outside in an ultra-low temperature state and a new substrate is introduced into the chamber, particles may be adsorbed to the substrate. Therefore, when the substrate is completely processed in an ultra-low temperature state, the substrate is held on stand-by for about 20 minutes until the temperature of the substrate returns to room temperature. During this process, refrigerant for cooling of the substrate needs to be replaced. When a substrate to be subsequently processed is introduced into the chamber after the previous substrate is discharged to the outside of the chamber, the substrate is cooled to ultra-low temperature from room temperature, and is then processed. During the process of cooling the substrate, the substrate is held on stand-by for about 20 minutes, and the refrigerant for cooling of the substrate is replaced.

That is, the stand-by time between processing processes is about 40 minutes. However, this stand-by time is excessively long compared to the processing time, which is generally about 20 minutes.

### SUMMARY

The present disclosure provides a substrate processing method capable of shortening a stand-by time between processing processes, a processing module, and semiconductor manufacturing equipment including the same.

A method of processing a substrate using plasma according to the present disclosure includes performing a processing process on a first substrate in the state in which the first substrate is seated on a support unit in a chamber defining a processing space therein and the temperature of the first substrate is maintained at a first temperature, forming plasma in the processing space to increase the temperature of the first substrate to a second temperature, higher than the first temperature, when the processing process performed on the first substrate is completed, transferring the first substrate to the outside of the chamber when the temperature of the first substrate reaches the second temperature and placing a second substrate onto the support unit, and lowering the temperature of the second substrate to the first temperature and performing a processing process on the second substrate.

In the embodiment of the present disclosure, the first temperature may be −70° C.

In the embodiment of the present disclosure, the second temperature may be 25° C.

In the embodiment of the present disclosure, the processing process performed on the first substrate and the second substrate may be a dry etching process using plasma, which is performed by supplying first radio-frequency (RF) power in the state in which first process gas is supplied to the processing space.

In the embodiment of the present disclosure, increasing the temperature of the first substrate to the second temperature may be performed by supplying second RF power in the state in which second process gas is supplied to the processing space.

In the embodiment of the present disclosure, the first process gas may be an etchant for etching of the first substrate and the second substrate, and the second process gas may be argon (Ar) gas.

In the embodiment of the present disclosure, the second RF power may be power lower than the first RF power.

A processing module for performing a processing process on a substrate according to the present disclosure includes a chamber defining a processing space therein, a support unit located at a lower portion in the processing space, a gas supply unit configured to supply process gas to the interior of the chamber, and an RF power supply configured to supply RF power for generation of plasma. The processing module performs the substrate processing method described above.

Semiconductor manufacturing equipment according to the present disclosure includes a loader module accommodating a cassette configured to receive a substrate, the loader module being configured to unload or load the substrate from or into the cassette, a processing module configured to perform a processing process on the substrate, a transfer module configured to transfer the substrate between the loader module and the processing module, and a controller configured to control operation of the processing module and the transfer module. The processing module includes a chamber having defined therein a processing space for processing of the substrate, a support unit located at a lower portion in the processing space, a gas supply unit configured to supply process gas to the interior of the chamber, and an RF power supply configured to supply RF power for generation of plasma.

The controller is configured to perform a processing process on a first substrate in the state in which the first substrate is seated on the support unit and the temperature of the first substrate is maintained at a first temperature, form plasma in the processing space to increase the temperature of the first substrate to a second temperature, higher than the first temperature, when the processing process performed on the first substrate is completed, transfer the first substrate to the outside of the chamber when the temperature of the first substrate reaches the second temperature and place a second substrate onto the support unit, and lower the temperature of the second substrate to the first temperature and perform a processing process on the second substrate.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows the layout of semiconductor manufacturing equipment according to the present disclosure;

FIG. 2 shows the structure of a processing module according to the present disclosure;

FIG. 3 shows the structure of a support unit in the processing module according to the present disclosure;

FIG. 4 is a flowchart showing a substrate processing method according to the present disclosure; and

FIGS. 5A to 5D are views for explaining a substrate processing process according to the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

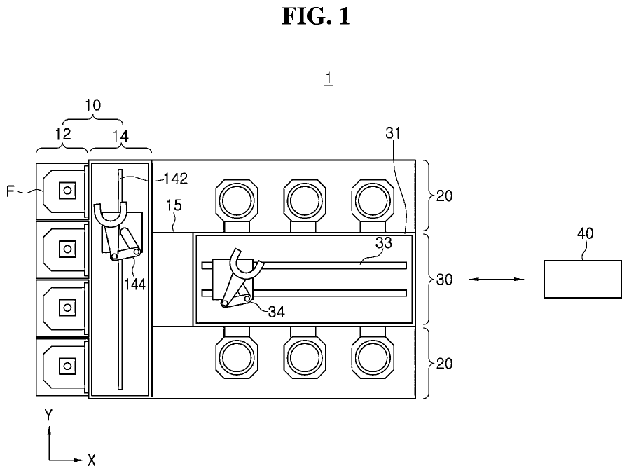

FIG. 1 shows the layout of semiconductor manufacturing equipment 1 according to the present disclosure. The semiconductor manufacturing equipment 1 to which the present disclosure is applicable is equipment that performs a processing process on a substrate using plasma. For example, the semiconductor manufacturing equipment 1 may be equipment that performs dry etching using plasma.

The semiconductor manufacturing equipment 1 according to an embodiment of the present disclosure includes a loader module 10, which accommodates a cassette F configured to receive a substrate W and unloads or loads a substrate from or into the cassette F, a processing module 20, which performs a processing process on the substrate W, a transfer module 30, which transfers the substrate W between the loader module 10 and the processing module 20, and a controller 40, which controls operation of the processing module 20 and the transfer module 30.

The loader module 10 includes a load port 12 on which the cassette F configured to receive a substrate is seated and an index unit 14 configured to unload a substrate from the cassette F seated on the load port 12 or to load a completely processed substrate into the cassette F. The load port 12 may be provided in plural, and the plurality of load ports 12 may be disposed in a predetermined direction (e.g., Y-axis direction) on an outer side of the semiconductor manufacturing equipment 1. After the cassette F transferred by an overhead hoist transport (OHT) is seated on each of the load ports 12, a door of the cassette F may be opened. The index unit 14 may be disposed adjacent to the load ports 12. The index unit 14 may include an index guide member 142 disposed in the arrangement direction (Y-axis direction) of the load ports 12 and an index robot 144 configured to transfer a substrate while moving along the index guide member 142. The index robot 144 may receive a substrate from the cassette F and then may transfer the received substrate to a load lock chamber 15 so that the substrate is temporarily stored in the load lock chamber 15, or may receive a substrate temporarily stored in the load lock chamber 15 and then may transfer the received substrate to the interior of the cassette F.

The processing module 20 is an apparatus that performs a processing process on a substrate, and may include one or more processing chambers. A plurality of processing chambers may be disposed in a predetermined direction (e.g., X-axis direction). The processing chambers may perform the same process or may perform different processes. For example, some of the processing chambers may perform an etching process on the substrate, and the remaining ones of the processing chambers may perform a cleaning process on the substrate having undergone the etching process.

The transfer module 30 may be disposed adjacent to the processing module 20. The transfer module 30 may receive a substrate from the load lock chamber 15 and then may transfer the received substrate to the processing module 20, or may transfer a substrate completely processed in the processing module 20 to the load lock chamber 15. The transfer module 30 may include a guide member 33 disposed in the arrangement direction (X-axis direction) of the processing chambers and a substrate transfer robot 34 configured to transfer a substrate while moving along the guide member 33.

The controller 40 may control overall operation of the semiconductor manufacturing equipment 1, particularly, operation of the processing module 20 and the transfer module 30. The controller may include a processor and a memory. The processor may execute commands for controlling operation of the semiconductor manufacturing equipment 1 and may perform data processing and calculation. The processor may be a central processing unit (CPU) or an application processor (AP). The processor may acquire and store data through communication with the memory and may control the memory.

The memory is provided to store data. The memory may store programs (e.g., an operating system and an application) for operation of the controller and data for execution of the programs. The memory may be random access memory (RAM), read-only memory (ROM), a hard disk drive (HDD), or a solid state drive (SSD). The memory may be connected to the processor via a data bus to transmit and receive data.

The controller 40 may include a communication module capable of communicating with an external entity and an input/output interface connected to input devices (e.g., a keyboard, a mouse, and a touch panel) and output devices (e.g., a display and a speaker) for interfacing with a user.

The processor may execute a desired process such as etching in accordance with various recipes stored in the memory. The recipes include apparatus control information for process conditions, including a process time, a process pressure, high-frequency power, a voltage, various gas flow rates, temperatures in the chamber (e.g., an electrode temperature, a chamber sidewall temperature, and an electrostatic chuck temperature), and the temperature of a cooler. The memory stores data on the recipes.

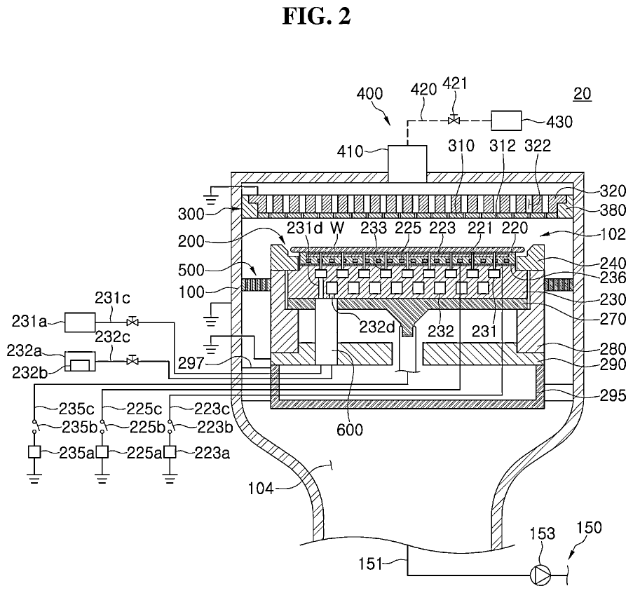

FIG. 2 shows the structure of a processing module 20 according to the present disclosure. The processing module 20 shown in FIG. 2 corresponds to one of the plurality of processing modules 20 of the semiconductor manufacturing equipment 1 shown in FIG. 1. In the semiconductor manufacturing equipment 1, the plurality of processing modules 20 may have the same structure.

Referring to FIG. 2, the processing module 20 includes a chamber 100, a support unit 200, a showerhead unit 300, a gas supply unit 400, a plasma source, a liner unit (not shown), and a baffle unit 500.

The chamber 100 has defined therein a processing space 102 in which a substrate processing process is performed. The chamber 100 is provided in a sealed shape. The chamber 100 may be made of a conductive material. For example, the chamber 100 may be made of a material including a metal. The chamber 100 may be made of aluminum. The chamber 100 may be grounded. An exhaust hole 104 is formed in the bottom surface of the chamber 100. The exhaust hole 104 is connected to an exhaust line 151. The exhaust line 151 is connected to a pump 153. Reaction by-products generated during the process and gas remaining in the space in the chamber 100 may be discharged to the outside through the exhaust line 151. The internal pressure of the chamber 100 is reduced to a predetermined level by the exhaust process. Alternatively, a separate pressure-reducing member may be provided to reduce the internal pressure of the processing space 102 to a predetermined level.

A heater (not shown) may be provided on the wall of the chamber 100. The heater heats the wall of the chamber 100. The heater is electrically connected to a heating power supply (not shown). The heater resists a current applied thereto from the heating power supply to generate heat. The heat generated by the heater is transferred to the internal space. The temperature in the processing space is maintained at a predetermined level by the heat generated by the heater. The heater may be provided as a coil-shaped heating wire. A plurality of heaters may be provided on the wall of the chamber 100.

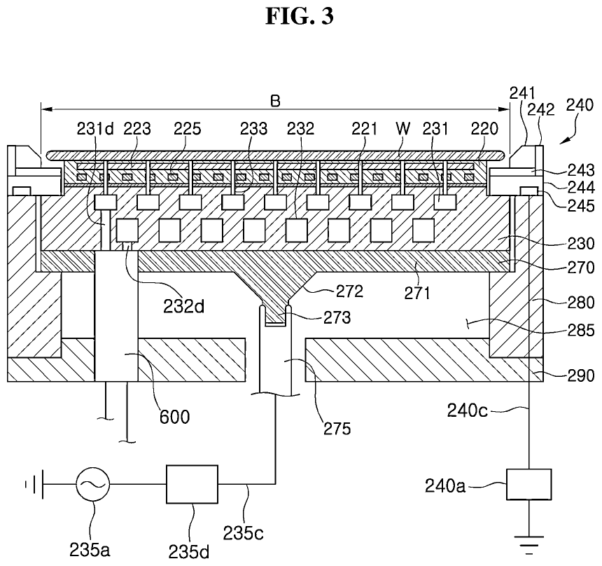

FIG. 3 shows the structure of the support unit 200 in the processing module 20 according to the present disclosure. The support unit 200 includes a dielectric plate 220, a metal plate 230, an edge ring assembly 240, a radio-frequency (RF) plate 270, an insulating cover 280, a base plate 290, a lower cover 295, and a fluid connection block 600. The support unit 200 may be located in the chamber 100 so as to be spaced upward from the bottom surface of the chamber 100.

The support unit 200 is located in the chamber 100. The support unit 200 supports the substrate W in the processing space. The support unit 200 may be provided as an electrostatic chuck (ESC) that attracts and holds the substrate W using electrostatic force. Alternatively, the support unit 200 may support the substrate W in various other ways, such as mechanical clamping.

The dielectric plate 220 is located at the top of the support unit 200. The dielectric plate 220 is provided as a disc-shaped dielectric substance. The substrate W is placed on the upper surface of the dielectric plate 220. The upper surface of the dielectric plate 220 has a smaller radius than the substrate W. Therefore, the peripheral area of the substrate W is located outside the dielectric plate 220. A first supply channel 221 is formed in the dielectric plate 220. The first supply channel 221 is formed from the upper surface of the dielectric plate 220 to the lower surface of the dielectric plate 220. A plurality of first supply channels 221 may be formed so as to be spaced apart from each other, and may serve as passages through which a heat transfer medium is supplied to the lower surface of the substrate W.

An electrostatic electrode 223 and a heater 225 are embedded in the dielectric plate 220. The electrostatic electrode 223 is located above the heater 225. The electrostatic electrode 223 is electrically connected to a direct-current (DC) power supply 223a. A switch 223b is mounted between the electrostatic electrode 223 and the DC power supply 223a. The electrostatic electrode 223 may be electrically connected to the DC power supply 223a by turning the switch 223b on/off. When the switch 223b is turned on, direct current is applied to the electrostatic electrode 223. Electrostatic force is exerted between the electrostatic electrode 223 and the substrate W by the current applied to the electrostatic electrode 223, and the substrate W is attracted to and held by the dielectric plate 220 due to the electrostatic force.

The heater 225 is electrically connected to a heater power supply 225a. The heater 225 resists a current applied thereto from the heater power supply 225a to generate heat. The generated heat is transferred to the substrate W through the dielectric plate 220. The temperature of the substrate W is maintained at a predetermined level by the heat generated by the heater 225. The heater 225 includes a spiral coil.

The metal plate 230 is located below the dielectric plate 220. The lower surface of the dielectric plate 220 and the upper surface of the metal plate 230 may be adhered to each other by means of an adhesive 236. The metal plate 230 may be made of aluminum. The upper surface of the metal plate 230 may be stepped such that the central area thereof is located at a position higher than the peripheral area thereof. The central area of the upper surface of the metal plate 230 has an area corresponding to the lower surface of the dielectric plate 220, and is adhered to the lower surface of the dielectric plate 220. A first circulation flow path 231, a second circulation flow path (refrigerant flow path) 232, and a second supply flow path 233 are formed in the metal plate 230.

The metal plate 230 may be connected to a high-frequency power supply via a high-frequency transmission line. Power may be applied to the metal plate 230 from the high-frequency power supply, so that plasma generated in the processing space may be smoothly supplied to the substrate. That is, the metal plate 230 may function as an electrode. In addition, although the processing module 20 is illustrated in FIG. 2 as being implemented as a capacitively coupled plasma (CCP) type, the disclosure is not limited thereto. The processing module 20 according to the embodiment of the present disclosure may be implemented as an inductively coupled plasma (ICP) type. When the processing module 20 is implemented as an ICP type, the high-frequency transmission line may be connected to a lower electrode for generating plasma to apply power from the high-frequency power supply to the lower electrode.

The first circulation flow path 231 is provided as a passage through which a heat transfer medium circulates. The first circulation flow path 231 may be formed in a spiral shape in the metal plate 230. Alternatively, a plurality of ring-shaped first circulation flow paths 231 may be disposed concentrically while having different radii. The plurality of first circulation flow paths 231 may communicate with each other. The first circulation flow paths 231 are formed at the same height.

The second circulation flow path 232 is provided as a passage through which a cooling fluid circulates. The second circulation flow path 232 may be formed in a spiral shape in the metal plate 230. Alternatively, a plurality of ring-shaped second circulation flow paths 232 may be disposed concentrically while having different radii. The plurality of second circulation flow paths 232 may communicate with each other. The second circulation flow paths 232 may have a greater cross-sectional area than the first circulation flow paths 231. The second circulation flow paths 232 are formed at the same height. The second circulation flow paths 232 may be located below the first circulation flow paths 231.

A plurality of second supply flow paths 233 extends upward from the first circulation flow paths 231 to the upper surface of the metal plate 230. The number of second supply flow paths 233 is identical to the number of first supply flow paths 221. The second supply flow paths 233 connect the first circulation flow paths 231 to the first supply flow paths 221.

The first circulation flow path 231 is connected to a heat transfer medium storage unit 231a via a first circulation flow path supply line 231d, the fluid connection block 600, and a heat transfer medium supply line 231c. A heat transfer medium is stored in the heat transfer medium storage unit 231a. The heat transfer medium includes inert gas. According to the embodiment, the heat transfer medium includes helium (He) gas. The helium gas is supplied to the fluid connection block 600 through the heat transfer medium supply line 231c, is supplied to the first circulation flow path 231 from the fluid connection block 600 through the first circulation flow path supply line 231d, and then is supplied to the lower surface of the substrate W from the first circulation flow path 231 through the second supply flow path 233. The helium gas serves as a medium through which heat transferred from the plasma to the substrate W is transferred to the electrostatic chuck.

The second circulation flow path 232 is connected to a cooling fluid storage unit 232a via a second circulation flow path supply line 232d, the fluid connection block 600, and a cooling fluid supply line 232c. A cooling fluid is stored in the cooling fluid storage unit 232a. A cooler 232b may be provided in the cooling fluid storage unit 232a. The cooler 232b cools the cooling fluid to a predetermined temperature. Alternatively, the cooler 232b may be mounted on the cooling fluid supply line 232c. The cooling fluid supplied to the fluid connection block 600 through the cooling fluid supply line 232c is supplied to the second circulation flow path 232 through the second circulation flow path supply line 232d, and circulates along the second circulation flow path 232 to cool the metal plate 230. As the metal plate 230 is cooled, the dielectric plate 220 and the substrate W are also cooled, whereby the temperature of the substrate W is maintained at a predetermined level.

The edge ring assembly 240 is disposed in the peripheral area of the electrostatic chuck. The edge ring assembly 240 has a ring shape and is disposed along the periphery of the dielectric plate 220. In addition, the edge ring assembly 240 may be disposed on the upper surface of the insulating cover 280. Referring to FIG. 3, the edge ring assembly 240 includes a focus ring 241 and an upper insulating ring 242. The focus ring 241 is formed on an inner side of the upper insulating ring 242 so as to surround the dielectric plate 220. The focus ring 241 may be made of silicon, and may focus ions generated during the plasma process on the peripheral portion of the substrate W. The upper insulating ring 242 is formed on an outer side of the focus ring 241 so as to surround the focus ring 241. The upper insulating ring 242 may be made of quartz.

A metal ring 243 made of aluminum is formed on a lower side of the focus ring 241. A lower insulating ring 244 made of an insulating material is formed on lower sides of the metal ring 243 and the upper insulating ring 242. An edge electrode ring 245 is inserted into the lower insulating ring 244. The edge electrode ring 245 is made of a conductive material. The edge electrode ring 245 is connected to an edge impedance control circuit 240a via an edge electrode line 240c. The edge electrode ring 245 is provided to control the impedance of a peripheral portion of the support unit 200. The edge electrode ring 245 corresponds to an edge electrode.

The edge impedance control circuit 240a includes one or more impedance elements (capacitors and inductors). At least one of the impedance elements of the edge impedance control circuit 240a may be a variable impedance element (e.g., a variable capacitor).

An air gap 285 is formed below the metal plate 230. The air gap 285 is formed between the RF plate 270 and a base plate 290 to be described later. The air gap 285 may be surrounded by the insulating cover 280. The air gap 285 electrically insulates the RF plate 270 and the base plate 290 from each other.

The RF plate 270 is provided below the metal plate 230. The upper surface of the RF plate 270 is in contact with the lower surface of the metal plate 230. The planar shape of the RF plate 270 may be a disc shape. The RF plate 270 is made of a conductive material. For example, the RF plate 270 may be made of aluminum. The RF plate 270 corresponds to an RF electrode.

The RF plate 270 includes an electrode plate portion 271, a deformed portion 272, and a rod coupling portion 273. The electrode plate portion 271 is formed to have a planar shape corresponding to the planar shape of the metal plate 230. The deformed portion 272 extends downward from the center of the electrode plate portion 271. The deformed portion 272 may be formed such that the diameter thereof gradually decreases in a downward direction. The rod coupling portion 273 extends downward from the lower side of the deformed portion 272.

A power supply rod 275 may apply power to the RF plate 270. The power supply rod 275 may be electrically connected to the RF plate 270. The power supply rod 275 may be connected to an RF power supply 235a. The RF power supply 235a generates RF power. The RF power supply 235a may be provided as a high bias power RF power supply. The RF power supply 235a may include a plurality of RF power supplies. The plurality of RF power supplies may be configured as a combination of one or more of high frequency (27.12 MHz or higher), medium frequency (1 MHz to 27.12 MHz), and low frequency (100 kHz to 1 MHz). The power supply rod 275 receives high-frequency power from the RF power supply 235a. The power supply rod 275 may be made of a conductive material. For example, the power supply rod 275 may be made of a material including a metal. The power supply rod 275 may be a metal rod. In addition, the power supply rod 275 may be connected to an impedance matching circuit 235d. The RF power supply 235a and the power supply rod 275 may be connected to each other via the impedance matching circuit 235d. The impedance matching circuit 235d includes impedance elements for impedance matching so that maximum power is transferred from the RF power supply 235a to the plasma load. The impedance matching circuit 235d includes one or more impedance elements (capacitors and inductors). At least one of the impedance elements of the impedance matching circuit 235d may be a variable impedance element (e.g., a variable capacitor).

The insulating cover 280 supports the RF plate 270. The insulating cover 280 may be provided so as to be in contact with the side surface of the RF plate 270. The insulating cover 280 may be provided so as to be in contact with a peripheral area of the lower surface of the RF plate 270. For example, the insulating cover 280 may have a tubular shape having open upper and lower portions. In addition, the insulating cover 280 may have a stepped inner side so that the RF plate 270 is supported by the insulating cover 280. The insulating cover 280 may be made of an insulative material.

The base plate 290 is configured to be electrically grounded. A through-hole through which the power supply rod 275 passes is formed in the center of the base plate 290.

The fluid connection block 600 is coupled to the RF plate 270 and the base plate 290 on the lower surface of the metal plate 230. The fluid connection block 600 supplies the heat transfer medium supplied from the heat transfer medium supply line 231c and the cooling fluid supplied from the cooling fluid supply line 232c to the first circulation flow path 231 and the second circulation flow path 232, respectively.

The lower cover 295 is located at the bottom of the support unit 200. The lower cover 295 is spaced upward from the bottom of the chamber 100. The lower cover 295 has defined therein a space having an open upper surface. The upper surface of the lower cover 295 is covered by the base plate 290. Therefore, the outer radius of the cross-section of the lower cover 295 may be formed to be identical to the outer radius of the base plate 290. A lift pin module (not shown), which moves a substrate W transferred from an external transfer member to a substrate support surface, i.e., the upper surface of the support unit 200, may be provided in the space in the lower cover 295.

The lower cover 295 includes a connecting member 297. The connecting member 297 connects the outer side surface of the lower cover 295 to the inner side wall of the chamber 100. A plurality of connecting members 297 may be provided at regular intervals on the outer side surface of the lower cover 295. The connecting members 297 support the support unit 200 in the chamber 100. In addition, the connecting members 297 are connected to the inner side wall of the chamber 100 so that the lower cover 295 is electrically grounded. A DC power line 223c connected to the DC power supply 223a, a non-sinusoidal wave power line 224c connected to a non-sinusoidal wave power supply 224a, a heater power line 225c connected to the heater power supply 225a, an RF power line 235c connected to the RF power supply 235a, the heat transfer medium supply line 231c connected to the heat transfer medium storage unit 231a, and the cooling fluid supply line 232c connected to the cooling fluid storage unit 232a extend to the interior of the lower cover 295 through spaces in the connecting members 297.

The lower cover 295 is disposed below the insulating cover 280. The lower cover 295 is disposed below the insulating cover 280 to support the insulating cover 280. In addition, the lower cover 295 may be made of a conductive material. For example, the lower cover 295 may be made of a material including a metal. In addition, the lower cover 295 may be electrically connected to the chamber 100. The lower cover 295 may be electrically grounded.

Referring to FIG. 2, the showerhead unit 300 may disperse gas supplied from above. In addition, the showerhead unit 300 may allow gas supplied from the gas supply unit 400 to be uniformly supplied to the processing space. The showerhead unit 300 includes a showerhead 310 and a gas spray plate 320.

The showerhead 310 is disposed below the gas spray plate 320. The showerhead 310 is spaced downward from the top surface of the chamber 100 by a predetermined distance. The showerhead 310 is located above the support unit 200. A certain space is defined between the showerhead 310 and the top surface of the chamber 100. The showerhead 310 may be formed in a plate shape having a constant thickness. The lower surface of the showerhead 310 may be anodized in order to prevent the occurrence of arc due to plasma. The showerhead 310 may be formed to have the same cross-sectional shape and cross-sectional area as the support unit 200. A plurality of gas supply holes 312 is formed in the showerhead 310. The gas supply holes 312 may be formed so as to vertically penetrate the upper and lower surfaces of the showerhead 310.

The showerhead 310 may be made of a material that reacts with plasma generated from gas supplied from the gas supply unit 400 to generate a compound. For example, the showerhead 310 may be made of a material that reacts with an ion having the highest electronegativity among ions included in the plasma to generate a compound. For example, the showerhead 310 may be made of a material including silicon (Si).

The gas spray plate 320 is disposed on the showerhead 310. The gas spray plate 320 is spaced a predetermined distance from the top surface of the chamber 100. The gas spray plate 320 may diffuse gas supplied from above. A plurality of gas introduction holes 322 may be formed in the gas spray plate 320. The gas introduction holes 322 may be formed at positions corresponding to the above-described gas supply holes 312. The gas introduction holes 322 may communicate with the gas supply holes 312. The gas supplied from above the showerhead unit 300 may sequentially pass through the gas introduction holes 322 and the gas supply holes 312, and may then be supplied to a lower portion of the showerhead 310. The gas spray plate 320 may include a metal. The gas spray plate 320 may be grounded. The gas spray plate 320 may be grounded to function as an upper electrode.

An insulating ring 380 is disposed so as to surround the peripheries of the showerhead 310 and the gas spray plate 320. The insulating ring 380 may be formed in a circular ring shape on the whole. The insulating ring 380 may be made of a nonmetallic material.

The gas supply unit 400 supplies process gas to the interior of the chamber 100. The gas supply unit 400 includes a gas supply nozzle 410, a gas supply line 420, and a gas storage unit 430. The gas supply nozzle 410 may be mounted to the central portion of the top of the chamber 100. An injection port is formed in the bottom surface of the gas supply nozzle 410. The process gas supplied through the gas supply nozzle 410 passes through the showerhead unit 300, and is supplied to the processing space in the chamber 100. The gas supply line 420 connects the gas storage unit 430 to the gas supply nozzle 410. The gas supply line 420 supplies the process gas stored in the gas storage unit 430 to the gas supply nozzle 410. A valve 421 is mounted on the gas supply line 420. The valve 421 opens and closes the gas supply line 420 to control the flow rate of the process gas supplied through the gas supply line 420.

The gas supplied from the gas supply unit 400 may be excited to a plasma state by a plasma source. In addition, the gas supplied from the gas supply unit 400 may be a gas containing fluorine. For example, the gas supplied from the gas supply unit 400 may be carbon tetrafluoride.

The plasma source excites the process gas to a plasma state in the chamber 100. In the embodiment of the present disclosure, capacitively coupled plasma (CCP) is used as a plasma source. The capacitively coupled plasma may include an upper electrode and a lower electrode in the chamber 100. The upper electrode and the lower electrode may be disposed parallel to each other at an upper portion and a lower portion in the chamber 100. One of the two electrodes may apply high-frequency power, and the other thereof may be grounded. An electromagnetic field may be formed in the space between the two electrodes, and the process gas supplied to this space may be excited to a plasma state. A substrate processing process is performed using this plasma. In one example, the upper electrode may be provided as the showerhead unit 300, and the lower electrode may be provided as the RF plate 270. High-frequency power may be applied to the lower electrode, and the upper electrode may be grounded. Alternatively, high-frequency power may be applied to both the upper electrode and the lower electrode. Accordingly, an electromagnetic field is generated between the upper electrode and the lower electrode. The generated electromagnetic field excites the process gas supplied to the interior of the chamber 100 to a plasma state.

The liner unit (not shown) prevents the inner wall of the chamber 100 and the support unit 200 from being damaged during the process. The liner unit (not shown) prevents impurities generated during the process from being deposited on the inner wall of the chamber 100 and the support unit 200. The liner unit (not shown) includes an inner liner (not shown) and an outer liner (not shown).

The outer liner (not shown) is provided on the inner wall of the chamber 100. The outer liner (not shown) has defined therein a space having open upper and lower surfaces. The outer liner (not shown) may be formed in a cylindrical shape. The outer liner (not shown) may have a radius corresponding to the inner side surface of the chamber 100. The outer liner (not shown) is provided along the inner side surface of the chamber 100. The outer liner (not shown) may be made of aluminum. The outer liner (not shown) protects the inner side surface of the chamber 100. During the process in which the process gas is excited, arc discharge may occur in the chamber 100. Arc discharge damages the chamber 100. The outer liner (not shown) protects the inner side surface of the chamber 100 by preventing the inner side surface of the chamber 100 from being damaged by arc discharge.

The inner liner (not shown) is provided so as to surround the support unit 200. The inner liner (not shown) is formed in a ring shape. The inner liner (not shown) is provided so as to surround the insulating cover 280. The inner liner (not shown) may be made of aluminum. The inner liner (not shown) protects the outer side surface of the support unit 200.

The baffle unit 500 is located between the inner side wall of the chamber 100 and the support unit 200. The baffle unit 500 is formed in an annular ring shape. A plurality of through-holes is formed in the baffle unit 500. The gas supplied to the interior of the chamber 100 passes through the through-holes in the baffle unit 500, and is discharged to the exhaust hole 104. The flow of the gas may be controlled in accordance with the shape of the baffle unit 500 and the shape of the through-holes.

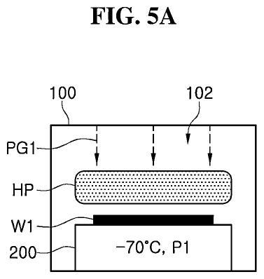

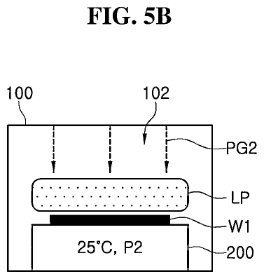

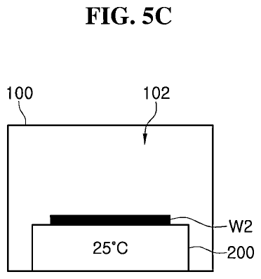

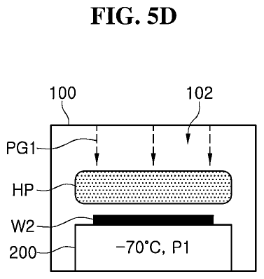

Hereinafter, a substrate processing method according to the present disclosure will be described. Among processes of processing a substrate W using plasma, a dry etching process using plasma at ultra-low temperature (e.g., −70° C.) is known. In order to create an ultra-low temperature environment, refrigerant for ultra-low temperature is supplied to the second circulation flow path 232 in the metal plate 230. A processing process is performed on the substrate W using plasma in an ultra-low temperature state. As shown in FIGS. 5A to 5D, when a first substrate W1 is completely processed, the first substrate W1 is discharged to the outside of the chamber 100, a second substrate W2 for a subsequent process is introduced into the chamber 100, and the processing process is again performed on the second substrate W2 in an ultra-low temperature environment.

However, if the ultra-low temperature environment is maintained as is when the first substrate W1 is discharged to the outside of the chamber 100 or the second substrate W2 is introduced into the chamber 100, a large amount of particles may be adsorbed to the first substrate W1 or the second substrate W2. Therefore, the temperature of the processing space 102 needs to return to room temperature (e.g., 25° C.) during a stand-by time during which the first substrate W1 is discharged or the second substrate W2 is introduced. That is, when the first substrate W1 is completely processed in an ultra-low temperature state, the refrigerant for ultra-low temperature needs to be discharged to the outside, and the first substrate W1 needs to be held on stand-by until the temperature of the first substrate W1 returns to room temperature. A time required for the temperature of the first substrate W1 to return from the ultra-low temperature to room temperature is about 20 minutes.

In addition, in order to again create an ultra-low temperature environment after introduction of the second substrate W2 into the chamber 100 at room temperature, the refrigerant for ultra-low temperature needs to be supplied to the second circulation flow path 232 in the metal plate 230, and the second substrate W2 needs to be held on stand-by until the temperature of the second substrate W2 reaches ultra-low temperature from room temperature. This process also takes about 20 minutes. That is, the stand-by time between the two processing processes is about 40 minutes. Considering that a plasma processing process generally takes about 20 minutes, the stand-by time of about 40 minutes is excessively long. Therefore, the present disclosure provides a substrate processing method capable of shortening the stand-by time between processing processes.

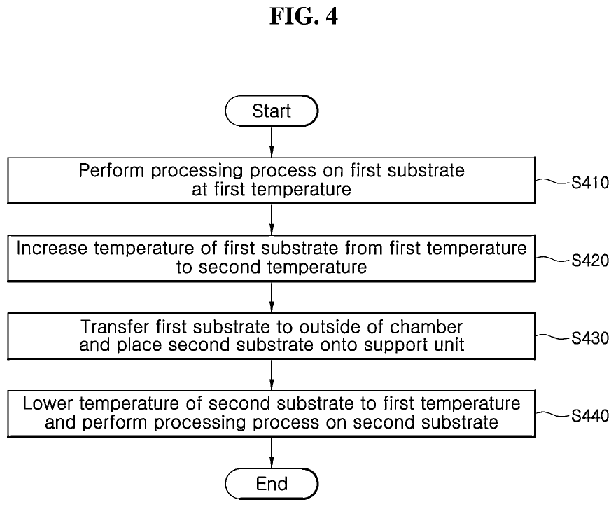

FIG. 4 is a flowchart showing a substrate processing method according to the present disclosure. The substrate processing method according to the present disclosure may be executed by the processing module 20 under the control of the controller 40. The processing module 20 according to the present disclosure includes a chamber 100 having a processing space 102 defined therein, a support unit 200 located at a lower portion in the processing space 102, a gas supply unit 400 configured to supply process gas to the interior of the chamber 100, and an RF power supply 235a configured to supply RF power for generation of plasma.

The substrate processing method according to the present disclosure includes a step of performing a processing process on the first substrate W1 in the state in which the first substrate W1 is seated on the support unit 200 in the chamber 100 defining the processing space 102 therein and the temperature of the first substrate W1 is maintained at a first temperature (S410), a step of forming plasma in the processing space 102 to increase the temperature of the first substrate W1 to a second temperature, higher than the first temperature, when the processing process performed on the first substrate W1 is completed (S420), a step of transferring the first substrate W1 to the outside of the chamber 100 when the temperature of the first substrate W1 reaches the second temperature and placing the second substrate W2 onto the support unit 200 (S430), and a step of performing a processing process on the second substrate W2 in the state in which the temperature of the second substrate W2 is lowered to the first temperature (S440). The first temperature is a temperature corresponding to ultra-low temperature, which is about −70° C., and the second temperature is a temperature corresponding to room temperature, which is about 25° C.

In step S410, a processing process is performed on the first substrate W1 in the state in which the first substrate W1 is seated on the support unit 200 in the chamber 100 and the temperature of the first substrate W1 is maintained at the first temperature. The controller 40 performs a processing process on the first substrate W1 in the state in which the first substrate W1 is seated on the support unit 200 in the chamber 100 and the temperature of the first substrate W1 is maintained at the first temperature. In more detail, the first substrate W1 is seated on the upper surface of the dielectric plate 220 by the substrate transfer robot 34, and the first substrate W1 is tightly attracted to the dielectric plate 220 by electrostatic force applied to the electrostatic electrode 223. In order to create an ultra-low temperature environment, the refrigerant for ultra-low temperature stored in the cooling fluid storage unit 232a is supplied to the second circulation flow path 232 in the metal plate 230 via the cooling fluid supply line 232c, the fluid connection block 600, and the second circulation flow path supply line 232d.

When the temperature of the first substrate W1 reaches the first temperature, a processing process may be performed on the first substrate W1. Here, the processing process performed on the first substrate W1 is a dry etching process using plasma, which is performed by supplying first RF power P1 in the state in which first process gas PG1 is supplied to the processing space 102. The first process gas PG1 is supplied to the processing space 102 through the gas supply unit 400 and the showerhead unit 300, and the first RF power is applied to the lower electrode (RF plate 270) of the support unit 200 from the RF power supply 235a, whereby plasma is generated in the processing space 102. The first process gas is an etchant for etching of the first substrate W1. The etchant may include fluorine (F₂), hydrogen fluoride (HF), or chlorine (Cl₂). As shown in FIG. 5A, plasma for dry etching of the first substrate W1 is formed by supplying the first process gas PG1 to the processing space 102 in the chamber 100 at temperature of −70° C. and supplying the first RF power to the lower electrode (RF plate 270) of the support unit 200. A specific material on the first substrate W1 is etched by the plasma. The plasma generated at this time is high-temperature plasma HP of several hundred to several thousand degrees Celsius (C) having high ion and electronic energy for etching of the first substrate W1.

In step S420, when the processing process performed on the first substrate W1 is completed, plasma is formed in the processing space 102 to increase the temperature of the first substrate W1 to the second temperature higher than the first temperature. When the processing process performed on the first substrate W1 is completed, the controller 40 forms plasma in the processing space 102 to increase the temperature of the first substrate W1 to the second temperature higher than the first temperature. In more detail, when the processing process performed on the first substrate W1 is completed, the supply of the first RF power P1 is interrupted, the first process gas PG1 used for the processing process is discharged to the outside through the baffle unit 500, and the refrigerant remaining in the second circulation flow path 232 is discharged to the outside. Thereafter, in the state in which the first substrate W1 is seated on the support unit 200, plasma for control of the temperature of the first substrate W1 is generated, so that the temperature of the first substrate W1 is increased from the first temperature to the second temperature.

As shown in FIG. 5B, the process of increasing the temperature of the first substrate W1 to the second temperature is performed by supplying second RF power P2 in the state in which second process gas PG2 is supplied to the processing space 102. The second process gas PG2 is supplied to the processing space 102 through the gas supply unit 400 and the showerhead unit 300, and the second RF power is applied to the lower electrode (RF plate 270) of the support unit 200 from the RF power supply 235a, whereby plasma is generated in the processing space 102. The plasma generated at this time is low-temperature plasma LP of several tens of degrees Celsius (° C.) for controlling the temperature of the first substrate W1 to the second temperature. The second process gas PG2 for generation of the low-temperature plasma LP is argon (Ar) gas. The second RF power P2 for generation of the low-temperature plasma LP is power lower than the first RF power P1.

In step S430, when the temperature of the first substrate W1 reaches the second temperature, the first substrate W1 is transferred to the outside of the chamber 100, and the second substrate W2 is placed on the support unit 200. When the temperature of the first substrate W1 reaches the second temperature, the controller 40 transfers the first substrate W1 to the outside of the chamber 100, and places the second substrate W2 onto the support unit 200. In more detail, when the temperature of the first substrate W1 reaches the second temperature, the substrate transfer robot 34 transfers the first substrate W1 to the outside of the chamber 100, and then places the first substrate W1 in the load lock chamber 15. Thereafter, the substrate transfer robot 34 places the second substrate W2 onto the support unit 200 in the chamber 100. As shown in FIG. 5C, the first substrate W1 is discharged to the outside of the chamber 100 at the second temperature, and the second substrate W2 is seated on the support unit 200.

According to the present disclosure, since the temperature of the first substrate W1 is controlled to room temperature using the low-temperature plasma, the stand-by time between processing processes may be greatly shortened compared to the related art in which the substrate should be held on stand-by for a certain time period. In particular, it is possible to increase the temperature of the first substrate W1 without replacing the refrigerant for ultra-low temperature, unlike the related art. The process of controlling the temperature of the first substrate W1 using plasma takes about 1 minute, and it takes about 20 seconds from placement of the second substrate W2 onto the support unit 200 to commencement of the processing process. In this way, the stand-by time is greatly shortened compared to the related art in which it takes about 40 minutes from adjustment from the first temperature to the second temperature through replacement of the refrigerant to adjustment from the second temperature to the first temperature through replacement of the refrigerant.

In step S440, the temperature of the second substrate W2 is lowered to the first temperature, and the processing process is performed on the second substrate W2. The controller 40 lowers the temperature of the second substrate W2 to the first temperature, and performs the processing process on the second substrate W2. Similar to step S410, the second substrate W2 is tightly attracted to the dielectric plate 220 by electrostatic force applied to the electrostatic electrode 223. In order to create an ultra-low temperature environment, the refrigerant for ultra-low temperature stored in the cooling fluid storage unit 232a is supplied to the second circulation flow path 232 in the metal plate 230 via the cooling fluid supply line 232c, the fluid connection block 600, and the second circulation flow path supply line 232d.

When the temperature of the second substrate W2 reaches the first temperature, the processing process may be performed on the second substrate W2. Here, the processing process performed on the second substrate W2 is a dry etching process using plasma, which is performed by supplying the first RF power P1 in the state in which the first process gas PG1 is supplied to the processing space 102. The first process gas PG1 is supplied to the processing space 102 through the gas supply unit 400 and the showerhead unit 300, and the first RF power is applied to the lower electrode (RF plate 270) of the support unit 200 from the RF power supply 235a, whereby plasma is generated in the processing space 102. The first process gas is an etchant for etching of the second substrate W2. The etchant may include fluorine (F₂), hydrogen fluoride (HF), or chlorine (Cl₂). As shown in FIG. 5D, plasma for dry etching of the second substrate W2 is formed by supplying the first process gas PG1 to the processing space 102 in the chamber 100 at temperature of −70° C. and supplying the first RF power to the lower electrode (RF plate 270) of the support unit 200. A specific material on the second substrate W2 is etched by the plasma. The plasma generated at this time is high-temperature plasma HP of several hundred to several thousand degrees Celsius (° C.) having high ion and electronic energy for etching of the second substrate W2.

As is apparent from the above description, according to the present disclosure, when a processing process performed on a substrate is completed, the temperature of the substrate is increased using plasma. Accordingly, it is possible to shorten a stand-by time between processing processes.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A method of processing a substrate using plasma, the method comprising:
performing a processing process on a first substrate in a state in which the first substrate is seated on a support unit in a chamber defining a processing space therein and a temperature of the first substrate is maintained at a first temperature;
forming plasma in the processing space to increase the temperature of the first substrate to a second temperature, higher than the first temperature, when the processing process performed on the first substrate is completed;
transferring the first substrate to an outside of the chamber when the temperature of the first substrate reaches the second temperature and placing a second substrate onto the support unit; and
lowering a temperature of the second substrate to the first temperature and performing a processing process on the second substrate.

2. The method as claimed in claim 1, wherein the first temperature is −70° C.

3. The method as claimed in claim 1, wherein the second temperature is 25° C.

4. The method as claimed in claim 1, wherein the processing process performed on the first substrate and the second substrate is a dry etching process using plasma, and
wherein the dry etching process is performed by supplying first radio-frequency (RF) power in a state in which first process gas is supplied to the processing space.

5. The method as claimed in claim 4, wherein increasing the temperature of the first substrate to the second temperature is performed by supplying second RF power in a state in which second process gas is supplied to the processing space.

6. The method as claimed in claim 5, wherein the first process gas is an etchant for etching of the first substrate and the second substrate, and
wherein the second process gas is argon (Ar) gas.

7. The method as claimed in claim 5, wherein the second RF power is power lower than the first RF power.

8. A processing module for performing a processing process on a substrate, the processing module comprising:
a chamber defining a processing space therein;
a support unit located at a lower portion in the processing space;
a gas supply unit configured to supply process gas to an interior of the chamber; and
an RF power supply configured to supply RF power for generation of plasma,
wherein the processing module performs a substrate processing method comprising:
performing a processing process on a first substrate in a state in which the first substrate is seated on the support unit in the chamber defining the processing space therein and a temperature of the first substrate is maintained at a first temperature;
forming plasma in the processing space to increase the temperature of the first substrate to a second temperature, higher than the first temperature, when the processing process performed on the first substrate is completed;
transferring the first substrate to an outside of the chamber when the temperature of the first substrate reaches the second temperature and placing a second substrate onto the support unit; and
lowering a temperature of the second substrate to the first temperature and performing a processing process on the second substrate.

9. The processing module as claimed in claim 8, wherein the first temperature is −70° C.

10. The processing module as claimed in claim 8, wherein the second temperature is 25° C.

11. The processing module as claimed in claim 8, wherein the processing process performed on the first substrate and the second substrate is a dry etching process using plasma, and
wherein the dry etching process is performed by supplying first RF power in a state in which first process gas is supplied to the processing space.

12. The processing module as claimed in claim 11, wherein increasing the temperature of the first substrate to the second temperature is performed by supplying second RF power in a state in which second process gas is supplied to the processing space.

13. The processing module as claimed in claim 12, wherein the first process gas is an etchant for etching of the first substrate and the second substrate, and
wherein the second process gas is argon (Ar) gas.

14. The processing module as claimed in claim 12, wherein the second RF power is power lower than the first RF power.

15. Semiconductor manufacturing equipment comprising:
a loader module accommodating a cassette configured to receive a substrate, the loader module being configured to unload or load the substrate from or into the cassette;
a processing module configured to perform a processing process on the substrate;
a transfer module configured to transfer the substrate between the loader module and the processing module; and
a controller configured to control operation of the processing module and the transfer module,
wherein the processing module comprises:
a chamber having defined therein a processing space for processing of the substrate;
a support unit located at a lower portion in the processing space;
a gas supply unit configured to supply process gas to an interior of the chamber; and
an RF power supply configured to supply RF power for generation of plasma, and
wherein the controller is configured to:
perform a processing process on a first substrate in a state in which the first substrate is seated on the support unit and a temperature of the first substrate is maintained at a first temperature;
form plasma in the processing space to increase the temperature of the first substrate to a second temperature, higher than the first temperature, when the processing process performed on the first substrate is completed;
transfer the first substrate to an outside of the chamber when the temperature of the first substrate reaches the second temperature and place a second substrate onto the support unit; and
lower a temperature of the second substrate to the first temperature and perform a processing process on the second substrate.

16. The semiconductor manufacturing equipment as claimed in claim 15, wherein the first temperature is −70° C., and
wherein the second temperature is 25° C.

17. The semiconductor manufacturing equipment as claimed in claim 15, wherein the processing process performed on the first substrate and the second substrate is a dry etching process using plasma, and
wherein the dry etching process is performed by supplying first RF power in a state in which first process gas is supplied to the processing space.

18. The semiconductor manufacturing equipment as claimed in claim 17, wherein increasing the temperature of the first substrate to the second temperature is performed by supplying second RF power in a state in which second process gas is supplied to the processing space.

19. The semiconductor manufacturing equipment as claimed in claim 18, wherein the first process gas is an etchant for etching of the first substrate and the second substrate, and
wherein the second process gas is argon (Ar) gas.

20. The semiconductor manufacturing equipment as claimed in claim 18, wherein the second RF power is power lower than the first RF power.
